(19) United States
(12) Patent Application Publication
(10) Pub. No.: US 2017/0300240 A1
(43) Pub. Date: Oct. 19, 2017

(54) Mainframe to Commodity Computer Data Exchange

(71) Applicant: Paul Francis Gorlinsky, ELLENTON, FL (US)

(72) Inventor: Paul Francis Gorlinsky, ELLENTON, FL (US)

(21) Appl. No.: 15/477,324

(22) Filed: Apr. 3, 2017

Related U.S. Application Data
(60) Provisional application No. 62/322,533, filed on Apr. 14, 2016.

(51) Int. Cl. G06F 3/06; G11C 5/02; G06F 12/14

(52) U.S. Cl. CPC G06F 3/0611; G11C 5/025; G06F 3/0686; G06F 12/1408; G06F 3/0622; G06F 3/067; G06F 3/0665; G06F 2212/1052

(57) ABSTRACT

This invention solves many of the technological challenges to exchange information between IBM EBCDIC mainframe computers (mainframe computers, mainframe) and commodity computers (ASCII based PCs, computer servers, and the “Cloud”) in a cost effective, timely and reliable manner.

### TECHNICAL FIELD

The present invention relates to an apparatus and method(s) of exchanging data used by Mainframe computers and Commodity (PCs) computers with differing character encoding sets.

### BACKGROUND ART

Since nearly the beginning of the computer age, there has been, primarily, two distinct computer character encoding sets, ASCII, American Standard Code for Information Interchange, also known as ANSI X3.4, and EBCDIC, Extended Binary Coded Decimal Interchange Code. EBCDIC was a derivative from a 1950's developed character coding, BCD or BCDIC, and was deployed for use on IBM midrange and mainframe computers and operating systems about 1963/1964. The IBM mainframe operating system at that time was the first descendant of the present day z/OS operating system. ASCII development followed shortly afterwards and through a Presidential Executive order, was adopted as the primary character code set for most computers developed after 1968. As result of these events, IBM mainframe computers continued using EBCDIC as their primary character encoding and the PCs and computer servers, deployed today, use ASCII as their primary character encoding.

### BRIEF DESCRIPTION OF THE DRAWING(S)

FIG. 1 is a block diagram schematically illustrating an apparatus for mainframe to commodity computer data exchange according to an exemplary embodiment of the present invention.

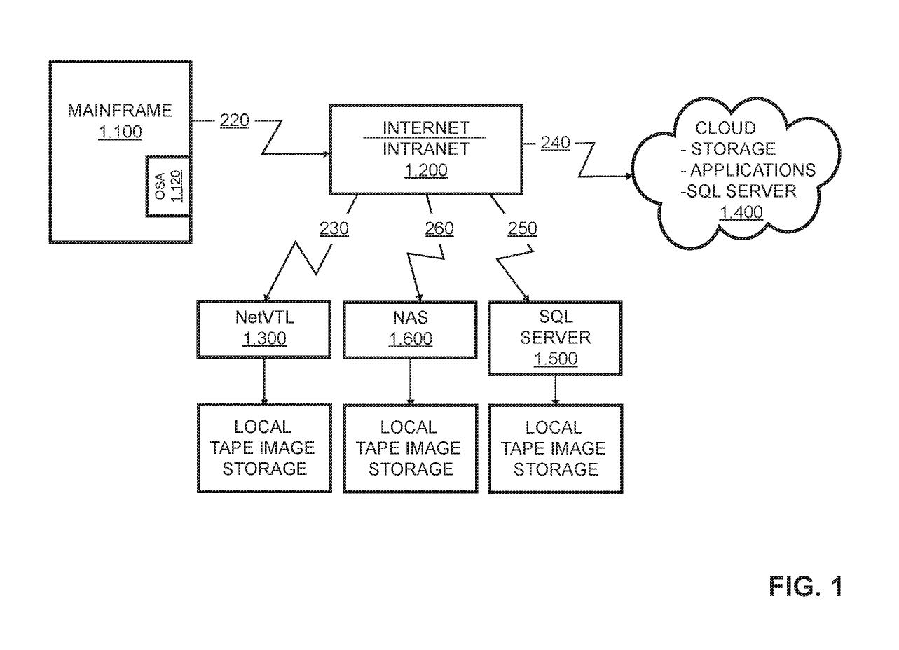

### LIST OF COMPONENT NUMERALS

1.100—IBM mainframe computer using an IBM MVS derivative operating system like IBM OS/390 or z/OS

1.120—IBM mainframe OSA (Open Systems Adapter) connection to Internet/Intranet infrastructure

1.200—Internet Protocol (IP) (Transmission Control Protocol (TCP)/User Datagram Protocol(UDP))—Enterprise Internet/Intranet infrastructure

220—Network connection to mainframe

230—Network connection to commodity computer

240—Network connection to Cloud Provider

250—Network connection to enterprise SQL server

260—Network connection to Network Attached Storage appliance (NAS)

1.300—Commodity computer hosting NetVTL server

1.400—Cloud provider hosting data storage, application execution, and database/SQL server

1.500—Enterprise database/SQL server

1.600—Network Attached Storage

How the Components Connect:

Mainframe computer (1.100) using its OSA card (1.120) is connected to the enterprise Internet/Intranet infrastructure (1.200). Cloud (1.400) provider is connect via enterprise Internet/Intranet infrastructure (1.200) at connector (240). Commodity computer hosting appliance application code for NetVTL (1.300) connected to the enterprise Internet/Intranet infrastructure (1.200) at connector (230). Enterprise SQL server (1.500) connected to the enterprise Internet/Intranet infrastructure (1.200) at connector (250). Network Attached Storage (NAS) appliance (1.600) connected to the enterprise Internet/Intranet infrastructure (1.200) at connector (260).

Operation:
1. Invention provides application interface code on the mainframe computer (1.100) that initiates a client connection to the commodity computer (1.300) hosting application server program emulating a virtual tape drive and library (NetVTL) using the IP network(1.200). The application interface code is a set of routines that process OPEN, GET, PUT, CLOSE, QUERY and SET mainframe operating system file functions.
2. Data is always encoded, for obfuscation, with a proprietary method prior to compression.
3. The OPEN function routine will start the IP connection with the NetVTL (1.300), passing parameters indicating what tape image file to use and additional parameters required to select the proper path to locate the tape image file. The NetVTL (1.300) will attempt to open an existing file or create the file automatically if not found. File path directory can be located on the NetVTL (1.300), a remote storage appliance, or Cloud provider storage (1.400).
4. The GET function routine will receive formatted data from the NetVTL (1.300) read “tape” image file, and de-blocks, decompresses and decodes the data, returning one or more blocks of data to the calling program.
5. The PUT function routine will encode, compress and block one or more records of data and send the resultant block of data to the NetVTL (1.300) to be de-blocked, decompressed, and decoded and to write one or more “tape” image file records.
6. The CLOSE function routine will terminate the connection with the NetVTL (1.300).
7. If the NetVTL (1.300) created a “tape” image file, then optionally, the NetVTL (1.300) will initiate a script to post-process the file. The script can be used to extract the sequential data from the “tape” image file, convert it from EBCDIC to ASCII, if necessary, and FTP the file to a remote commuter. The script may also initiate processes necessary to import the data into an SQL server(1.500), or as input into other application processes such as SMF (IBM z/OS Systems Management Facilities) reporting processing.
8. The QUERY function routine will initiate the exchange of statistics or other pertinent information from the NetVTL (1.300).
9. The SET function routine will initiate a change in operational parameters with the NetVTL (1.300). One such parameter would be the packet size. Another would be information related to the license key.
10. Application code incorporating the inventions application interface code would:
   10.1. Build the interface parameter, then call the OPEN routine.
   10.2. The OPEN routine will initiate an IP client connection to the NetVTL (1.300).
   10.3. The NetVTL (1.300) will locate or create the requested “tape” image file. The NetVTL (1.300) will open the file and return an appropriate return code to the OPEN routine on the mainframe computer.
   10.4. Following a successful OPEN call, the mainframe computer application code will initiate a repetitive call process for either GET or PUT as needed.
   10.5. The GET or PUT routine requests the NetVTL (1.300) to read or write blocks of tape data.
   10.6. To improve latency times with the IP connection, data is encode and compressed.
   10.7. The individual blocks of data will be queued until a full IP transmission packet has been built.
   10.8. When a full packet is built, it will be transmitted.
   10.9. The receiving side will de-block the transmitted packet, then decompress and decoded, the individual blocks will be returned to the caller one at a time.
   10.10. When all of the data has been transmitted, the CLOSE routine is called to complete the exchange of data and terminate the IP connection.
11. The NetVTL (1.300) initiates additional automation processes to a predetermined script call. Calling parameters to the script will include information indicating “tape” image file name, and other pertinent information from the “tape” image file, such as dataset name, attributes and count of records. The invention provides utility programs to extract the sequential file from the “tape” image file and create a file on the commodity computer. The utility will also convert from the mainframe computer's codepage to the commodity computer's codepage as requested.
12. The script can also be used to subsequently initiate FTP transfers, perform IBM RMF/SMF data reduction and reporting, insertion of data into SQL server (1.500) tables, or any number of additional applications that process data files.
13. The invention includes a utility to create “tape” image files from commodity computer data files. These files can be subsequently transmitted to the mainframe computer using the process described above.

Additional Uses:

The invention could also be used to archive or backup data from the mainframe computer (1.100) to be used to provide a Disaster Recovery(DR)/Business Continuity(BC) solution. Data from the NetVTL (1.300) could be stored in the Cloud (1.400), or a NAS (1.600), or other remote data storage devices inhibiting loss of primary critical information.

The invention could also be used to exchange information between mainframe computers. Two or more mainframe computers could access the same network attached remote data storage device.

The invention could also be used to exchange information between mainframe (1.100) and mainframe computer emulators such as IBM zPDT. The invention can read/write IBM AWS tape image files used by the zPDT emulator.

### REFERENCES

1. Using Magnetic Tape Labels and File Structure—IBM Corporation—SC26-4565 (1991) Trademark Information

IBM, z/OS, OS/390 and zPDT are registered trademarks of IBM Corporation MVS is a trademark of IBM Corporation

NetVTL is a trademark of Advanced TS Migrations, Co., Ellenton, Fla., USA

The invention claims are:

1. The invention implements an Internet Protocol (IP) network attached virtual tape library (NetVTL) appliance with advanced features to facility the exchange and transformation of data between mainframe computers and commodity computers.

2. The invention facilitates the storage and consumption, by commodity computers, of mainframe computers' data and by mainframe computers, of commodity computers' data.

3. (canceled)

4. The invention initiates all data exchanges from the mainframe computer, either sending data to or retrieving data from, the NetVTL hosted on a commodity computer.

5. The invention selects the “tape” image file, on commodity computer, from the mainframe computer initiated request using a six (6) alpha-numeric character string conforming to IBM z/OS tape label volume serial number specifications.

6. The invention obfuscates, compresses, buffers and optionally encrypts, using standard encryption methods, the data to be transmitted, on the IP network between the mainframe computer and the NetVTL, to improve data security and minimize latency issues associated with network data transmission.

7. (canceled)

8. (canceled)

9. (canceled)

10. The invention allows for the storage of “tape” image file on the local commodity computer, in the “Cloud,” or on other network attached data storage devices as a proprietary “tape” image file, or several other industry standard “tape ” image files, encoded in the mainframe computer's native character encoding, EBCDIC, or binary (unencoded).

11. (canceled)

12. The invention includes utility programs to convert the “tape” image file to a commodity computer sequential file, encoded in ASCII or other selected codepage, or as an unencoded binary; and to convert a commodity computer sequential file to “tape” image file to prepare for transmission to the mainframe computer. File may be encoded from the commodity computer codepage to EBCDIC (mainframe computer codepage) or remain as a binary file (unencoded).

13. The invention allows automated initiation a script and/or other application program to process data written to the NetVTL when transmission is completed. The automated process may be used to invoke invention utility programs to convert “tape” image file to a commodity computer formatted file and optionally, FTP the file to a remote destination, or import in to SQL server, or deploy data for additional commodity computer or “cloud computing” application processing.

14. (canceled)
